(19) United States
(12) Patent Application Publication
(10) Pub. No.: US 2025/0068432 A1
(43) Pub. Date: Feb. 27, 2025

(54) FLASH DRIVER CONTROL METHOD FOR MULTI-CORE MCU, AND DEVICE FOR IMPLEMENTING THE SAME

(71) Applicant: Hyundai AutoEver Corp., Seoul (KR)

(72) Inventor: Jae Hyun LIM, Seoul (KR)

(21) Appl. No.: 18/811,021

(22) Filed: Aug. 21, 2024

(30) Foreign Application Priority Data
Aug. 24, 2023 (KR) 10-2023-0111430

(51) Int. Cl. G06F 9/4401; G06F 9/48

(52) U.S. Cl. CPC G06F 9/4411; G06F 9/4881

(57) ABSTRACT

A flash driver control method performed in an MCU including a flash memory and a flash driver configured to perform a memory job on the flash memory includes executing a first task that executes a first main function for performing a first memory job and is terminated when the flash driver is idle, executing a second task that executes a second main function for performing a second memory job and is terminated when the flash driver is idle, and executing a third task that executes a third main function for requesting execution of a third memory job and is terminated when a third memory job completion response is received.

### CROSS REFERENCE TO RELATED APPLICATION

This application claims the benefit of and priority to Korea Patent Application No. 10-2023-0111430 filed on Aug. 24, 2023, the entire disclosure of which is hereby incorporated herein by reference in its entirety.

### FIELD OF TECHNOLOGY

The present disclosure relates to a technology for controlling a flash driver in a multi-core MCU, and more specifically, to a flash driver control technique for resolving duplicate access to a flash driver in a multi-core MCU for vehicles.

### BACKGROUND

While conventional automobiles were a collection of mechanical devices, recent automobiles are increasingly equipped with more and more electronic devices, and automobiles can now be said to be a collection of various electronic devices. As functions such as vehicle posture control, automatic parking, intelligent driving assistance, and autonomous driving become more common, more and more electronic devices are interconnected within automobiles.

As the number of electronic devices used in automobiles increases, the demand for standardization of software used therein increases, and accordingly, AUTOSAR, an embedded software open platform developed to increase the reusability of automobile software modules and the compatibility of individual vehicle parts, is widely used.

Meanwhile, an automobile microcontroller unit (MCU) is equipped with a code flash memory and a data flash memory, and the AUTOSAR flash module can directly access a flash memory through register access.

In the case of high-performance MCUs, code flash memory and data flash memory partitions are segmented, and a separate hardware device for accessing a flash memory is present, and thus Read-While-Write (RWW) constraint can be minimized and a problem of duplicate access to the flash memory can be prevented.

However, in the case of low-performance MCUs, since there is only one hardware device for accessing a flash memory, the RWW constraint may occur and the problem of duplicate access to the flash memory may occur.

For example, if a low-performance MCU is an MCU with a multi-core structure including a host core and a hardware security module (HSM) core, multiple programs each running on the host core and the HSM core may run concurrently, and multiple programs may also run concurrently on one core through context switching.

At this time, if multiple programs request a memory job to a hardware device for accessing one flash memory, only one memory job request may succeed while other memory job requests may fail, or the memory job requested first may even fail due to a duplicate request.

Therefore, in a low-performance multi-core MCU structure based on an AUTOSAR software platform, there is a need to resolve the problem of duplicate access to a flash memory in situations where programs are run concurrently on the host core and the HSM core or multiple programs are run concurrently on one core.

The discussions in this section are only to provide background information and do not constitute an admission of prior art.

### SUMMARY

An object of the present disclosure is to provide a method of controlling a flash driver of a multi-core MCU which can prevent multiple tasks executed in a host core of a low-performance multi-core MCU from accessing a flash driver repeatedly, and a device for implementing the same.

Another object of the present disclosure is to provide a method of controlling a flash driver of a multi-core MCU which can prevent multiple tasks executed in a host core and an HSM core of a low-performance multi-core MCU from accessing a flash driver repeatedly, and a device for implementing the same.

Another object of the present disclosure is to provide a method of controlling a flash driver of a multi-core MCU which can solve a problem of duplicate access to a flash driver that may occur in a low-performance multi-core MCU by utilizing the OS function of AUTOSAR, and a device for implementing the same.

Another object of the present disclosure is to provide a method of controlling a flash driver of a multi-core MCU which prevents mutual preemption between multiple tasks executed in a low-performance multi-core MCU and prevents a task from being terminated until a flash driver is idle and a device for implementing the same.

The objects of the present disclosure are not limited to the objects mentioned above, and other objects that are not mentioned above will be clearly understood by those skilled in the art of the present disclosure from the description below.

A method of controlling a flash driver of a multi-core MCU according to an embodiment of the present disclosure to achieve the aforementioned objects is a flash driver control method performed in a microcontroller unit (MCU) including a flash memory and a flash driver configured to perform a memory job on the flash memory, the flash driver control method including executing a first task that executes a first main function for performing a first memory job and is terminated when the flash driver is idle, executing a second task that executes a second main function for performing a second memory job and is terminated when the flash driver is idle, and executing a third task that executes a third main function for requesting execution of a third memory job and is terminated when a third memory job completion response is received.

In an embodiment, the MCU may be a multi-core MCU including a first core and a second core.

In an embodiment, the first core and the second core may include respective flash memories, and the flash memories may include data flash memories and code flash memories.

In an embodiment, wherein the memory job may be one of a read operation, a write operation, and an erase operation for data or code performed by the flash driver accessing the flash memory.

In an embodiment, the first task, the second task, and the third task may be executed as tasks having the same priority, background tasks, or extended tasks such that no preemption occurs among the first task, the second task, and the third task.

In an embodiment, the first memory job and the second memory job may be performed in the first core.

In an embodiment, the first memory job may perform the memory job on data of the data flash memory of the first core, and the second memory job may perform the memory job on code of the code flash memory of the first core.

In an embodiment, the first memory job or the second memory job may be performed in the first core, and the third memory job may be performed in the second core.

In an embodiment, the first core may be a host core, and the second core may be an HSM core.

In an embodiment, the first memory job may perform the memory job on data of the data flash memory of the first core, the second memory job may perform the memory job on code of the code flash memory of the first core, and the third memory job may perform the memory job on data of the data flash memory of the second core or perform the memory job on code of the code flash memory of the second core.

A method of controlling a flash driver of a multi-core MCU according to an embodiment of the present disclosure to achieve the aforementioned objects is a flash driver control method performed in an MCU including a flash driver configured to perform a memory job on a flash memory and a first core using the flash driver, the flash driver control method including a step in which a first task executes a first main function for performing a first memory job of the first core through the flash driver and is terminated when the flash driver is idle, and a step in which a second task executes a second main function for performing a second memory job of the first core through the flash driver and is terminated when the flash driver is idle.

In an embodiment, the flash memory may include a data flash memory and a code flash memory.

In an embodiment, the memory job may be one of a read operation, a write operation, and an erase operation for data or code performed by the flash driver accessing the flash memory.

In an embodiment, the first task and the second task may be executed as tasks having the same priority, background tasks, or extended tasks such that no preemption occurs between the first and second tasks.

In an embodiment, the first memory job may perform the memory job on data of the data flash memory of the first core, and the second memory job may perform the memory job on code of the code flash memory of the first core.

A method of controlling a flash driver of a multi-core MCU according to an embodiment of the present disclosure to achieve the aforementioned objects is a flash driver control method performed in an MCU including a flash driver configured to perform a memory job on a flash memory, and a first core and a second core using the flash driver, the flash driver control method including a step in which a first task executes a first main function for performing a first memory job of the first core and is terminated when the flash driver is idle or a second task executes a second main function for performing a second memory job of the first core and is terminated when the flash driver is idle, and a step in which a third task executes a third main function for requesting that the second core perform a third memory job of the second core and is terminated when a third memory job completion response is received from the second core.

In an embodiment, the first core may be a host core, and the second core may be an HSM core.

In an embodiment, the first memory job may perform the memory job on data of a data flash memory of the first core, the second memory job may perform the memory job on code of a code flash memory of the first core, and the third memory job may perform the memory job on data of a data flash memory of the second core or perform the memory job on code of a code flash memory of the second core.

In an embodiment, the first task, the second task, and the third task may be executed as tasks having the same priority, background tasks, or extended tasks such that no preemption occurs among the first task, the second task, and the third task.

A computing device according to an embodiment of the present disclosure to achieve the aforementioned objects is a computing device including a flash driver configured to perform a memory job on a flash memory, and a multi-core MCU including a first core and a second core using the flash driver, the computing device including one or more processors, a communication interface configured to communicate with an external device, a memory on which a computer program executed by the processor is loaded, and a storage device in which the computer program is stored, wherein the computer program includes instructions for performing an operation in which a first task executes a first main function for performing a first memory job of the first core and is terminated when the flash driver is idle, an operation in which a second task executes a second main function for performing a second memory job of the first core and is terminated when the flash driver is idle, and an operation in which a third task executes a third main function for requesting that the second core perform a third memory job of the second core and is terminated when a third memory job completion response is received from the second core.

In an embodiment, the first core may be a host core, and the second core may be an HSM core.

In an embodiment, the first memory job may perform the memory job on data of a data flash memory of the first core, the second memory job may perform the memory job on code of a code flash memory of the first core, and the third memory job may perform the memory job on data of a data flash memory of the second core or perform the memory job on code of a code flash memory of the second core.

In an embodiment, the first task, the second task, and the third task may be executed as tasks having the same priority, background tasks, or extended tasks such that no preemption occurs among the first task, the second task, and the third task.

According to the present embodiment, since multiple tasks running on the host core of a low-performance multi-core MCU can be prevented from accessing the flash driver repeatedly, software issues can be minimized by preventing unexpected termination of a program running on the host core. In addition, it is possible to maximize flash performance while preventing unexpected errors during program run-time and operate OTA (Over-The-Air) solutions more stably.

According to the present embodiment, it is possible to prevent multiple tasks running on the host core and the HSM core of a low-performance multi-core MCU from accessing the flash driver repeatedly, and thus costs can be reduced by preventing issues with the HSM core that cannot be debugged during mass production.

According to the present embodiment, since a problem of duplicate access to the flash driver that may occur in a low-performance multi-core MCU can be solved by utilizing the OS function of AUTOSAR, it is possible to reduce software complexity that occurs when global variables or non-standard methods are used, and it is possible to facilitate collaboration between developers since global variables do not have to be shared between developers.

According to the present embodiment, since mutual preemption between multiple tasks running on a low-performance multi-core MCU can be prevented and a task can be prevented from being terminated until the flash driver becomes idle, the performance of a single flash driver can be maximized. (Since the background task does not stop until the idle time is reached when a request occurs, a memory job can be performed more correctly than when the main function is run by being segmented several parts. The probability that a memory job request will occur repeatedly in all tasks is low, but even if it occurs repeatedly, the speed is faster than before.)

In addition, various effects that can be directly or indirectly identified through this specification can be provided.

### BRIEF DESCRIPTION OF THE DRAWINGS

In order for the disclosure to be well understood, there are now described various forms thereof, given by way of example, reference being made to the accompanying drawings, in which:

FIG. 1 is a configuration diagram illustrating an AUTOSAR platform used in an embodiment of the present disclosure;

FIG. 2 is a configuration diagram of an MCU having a multi-core structure according to an embodiment of the present disclosure;

FIG. 3 to FIG. 8 are flowcharts illustrating a method of controlling a flash driver of a multi-core MCU according to an embodiment of the present disclosure;

FIG. 9 is a flowchart illustrating a task execution steps according to several embodiments of the present disclosure; and

FIG. 10 is a hardware configuration diagram of an exemplary computing device capable of implementing methods according to several embodiments of the present disclosure.

### DETAILED DESCRIPTION

Hereinafter, embodiments of the present disclosure are described in detail with reference to the accompanying drawings. Advantages and characteristics of the present disclosure and methods to achieve them should be more clearly understood by referring to the accompanying drawings and the embodiments described below. However, the present disclosure is not limited to the below disclosed embodiments, but may be implemented in various types different from each other. The embodiments are provided only for completing the present disclosure and for completely teaching the scope of the present disclosure to a person having ordinary skill in the art to which the present disclosure pertains. The present disclosure is defined only by the scope of the claims and their equivalents.

In adding reference signs to components in each figure, it should be noted that the same components are denoted by the same signs as much as possible even if they are shown on different figures. In describing the present disclosure, a detailed description of a well-known configuration or function related to the present disclosure has been omitted where it was determined that the detailed description would unnecessarily obscure the gist of the present disclosure.

All terms (including technical or scientific terms) used in this specification have the same meanings as generally understood by a person having ordinary skill in the art to which the present disclosure pertains unless mentioned otherwise. Generally used terms, such as terms defined in a dictionary, should be interpreted to coincide with meanings of the related art from the context. Unless differently defined in the present disclosure, such terms should not be interpreted in an ideal or excessively formal manner. The terms used in this specification is for the purpose of describing embodiments only and is not intended to limit the present disclosure. In this specification, the singular expression includes the plural expression unless the context clearly dictates otherwise.

The terms “first”, “second”, A, B, (a), (b), etc. may be used herein to describe various elements of the present disclosure. These terms are only used to distinguish one element from another element and essential, order, or sequence of corresponding elements are not limited by these terms. It will be understood that when one element is referred to as being “connected to”, “coupled to”, or “access” another element, one element may be “connected to”, “coupled to”, or “access” another element via a third element although one element may be directly connected to or directly access another element.

The terms “comprise” and/or “comprising” used in the specification specify the presence of stated components, steps, operations, and/or elements, but do not preclude the presence or addition of one or more other components, steps, operations, and/or elements.

Hereinafter, some embodiments of the present disclosure will be described in detail with reference to the attached drawings.

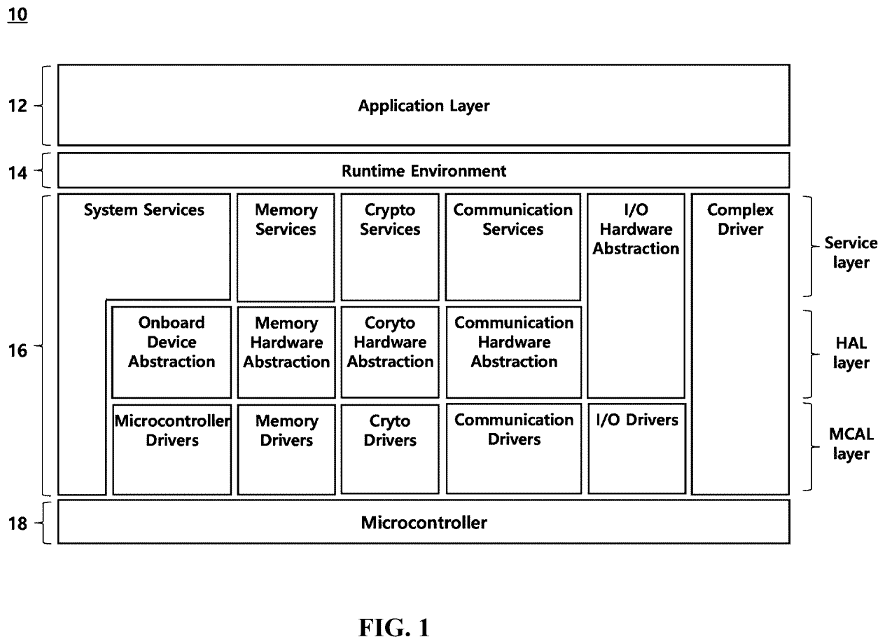

FIG. 1 is a configuration diagram illustrating an AUTOSAR platform used in an embodiment of the present disclosure.

Referring to FIG. 1, the AUTOSAR platform 10 may be composed of three layers, including an application layer 12, a runtime environment layer 14, and a basic software layer 16. The AUTOSAR (Automotive Open System Architecture) platform 10 may provide a layered standard software structure for improving compatibility, reusability, cost reduction, and reliability of automotive software. The AUTOSAR platform 10 may support multiple components having input/output ports and communicating with each other virtually through component-based software development (CBD).

The application layer 12 is the layer located at the top in the AUTOSAR platform structure and may be configured to include a software component (SWC; Software Component), which is a software module that performs a specific function. The application layer 12 may provide various functions and services of automobiles. For example, the application layer 12 may perform engine, automatic transmission, and brake control functions and may be arranged in a virtual network called a virtual functional bus (VFB) and operate in association with an electronic control unit (ECU).

The runtime environment layer (RTE) 14 is located between the application layer 12 and the basic software layer 16 and may provide an interface for data exchange between the application layer 12 and the basic software layer 16. The runtime environment layer 14 can be understood as a kind of middleware in that it performs communication connection between modules to provide the application layer 12 with independence that is not dependent on hardware.

The basic software layer (BSW) 16 is the lowest layer in the AUTOSAR platform structure and may provide services for performing tasks required by the application layer 12, such as an operating system (OS, device driver, and communication). The basic software layer 16 may be composed of a service layer, a hardware abstraction layer (HAL), and a microcontroller abstraction layer (MCAL).

The service layer may perform service functions such as system services, memory services, crypto services, and communication services, and the HAL may provide a transceiver or interface drivers that can use the MCAL above the MCAL for each lower device. The MCAL is a hardware-dependent part and may be composed of communication drivers of a data link layer of an OSI, an analog-to-digital converter (ADC), analog-digital I/O drivers for pulse width modulation (PWM), disk input/output (DIO), and the like, memory drivers that perform memory jobs on an EEPROM and a flash memory, and microcontroller drivers that drive a microcontroller 18.

In the illustrated configuration, the memory service area of the basic software layer 16 is composed of memory services, memory hardware abstraction, and memory drivers, and may provide functions for memory jobs. In addition, the security service area is composed of crypto services, crypto hardware abstraction, and crypto drivers, and may provide functions for hardware security.

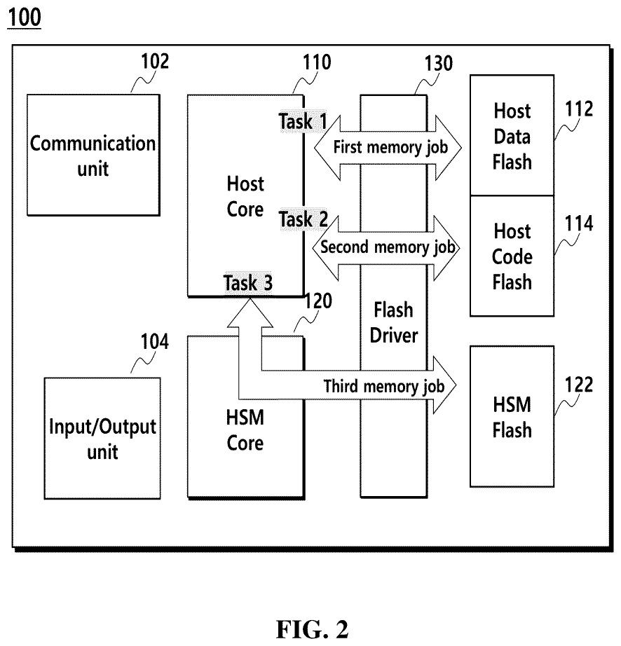

FIG. 2 is a configuration diagram of an MCU having a multi-core structure according to one embodiment of the present disclosure.

Referring to FIG. 2, the MCU 100 based on the AUTOSAR platform according to the embodiment of the present disclosure may be a low-performance MCU having a multi-core structure including a host core 110, an HSM core 120, a flash driver 130, flash memories 112, 114, and 122, a communication unit 102, and an input/output unit 104.

The low-performance MCU may be an MCU that needs to sequentially, concurrently, or repeatedly perform a plurality of memory jobs through one flash driver 130 when multiple programs or multiple cores require memory jobs. A memory job may be a task in which the flash driver 130 accesses a flash memory and performs one of a read operation, a write operation, and an erase operation for data or code. Memory jobs through the flash driver 130 may be performed by setting the relevant registers, and a write operation may be performed in block units and an erase operation may be performed in sector units.

The host core 110 includes a runtime environment RTE and an OS module in AUTOSAR, and may execute an application software component as a main arithmetic unit of the MCU. For example, the host core 110 is in charge of tasks such as execution of main application logic, data processing, and communication interface management, and may be a general-purpose core that mainly interacts with application programs and performs core functions of the system.

The host core 110 can have a data flash memory and a code flash memory that can be used by the host core 110. For example, the host core 110 may access the HostFlash 112 through the flash driver 130 and perform a memory job on data in the HostFlash 112. Here, the HostFlash data may be variables or data used for execution of main application logic and data processing. For example, the HostFlash data may include vehicle status information data, sensor data, control variable data, communication data, etc. (Task 1: Fls_MainFunction)

The host core 110 may access the HostFlash 114 through the flash driver 130 and perform a memory job on code in the HostFlash 114. For example, the host core 110 may access the HostFlash 112 through the flash driver 130 and perform a memory job on code in the HostFlash 112. Here, HostFlash code may be code responsible for executing main application logic. For example, the HostFlash code may include vehicle control algorithms (engine control, brake control, driving safety control, etc.), a communication protocol processing algorithm, state transition logic, etc. (Task 2: Ota_MainFunction)

The HSM core 120 may be a security-only core that processes tasks such as generation and management of encryption keys, encryption/decryption, digital signatures, and authentication. The HSM core 120 is physically separated from software and thus can protect the system from external malicious access and maintain the safety and confidentiality of data. For example, the HSM core 120 may protect the system by restricting booting of the host core 110, monitoring the operation of the host core 110, or blocking the JTAG interface for debugging.

The HSM core 120 is a separate core physically separated from the host core 110 in accordance with increase in networking and increase in requirements for data security in an AUTOSAR platform-based processor, and can reduce the load on the host core 110 by using a patented hardware accelerator when performing an encryption algorithm.

The HSM core 120 may have a flash memory that can be used exclusively. For example, the HSM core 120 may access the HSMFlash 122 through the flash driver 130 and perform a memory job on data or code in the HSMFlash 122. The HSM core 120 may partition the HSMFlash 122 to separate an area for data such as an encryption key from an area for security-related program code.

The HSM core 120 may perform a memory job on the HSMFlash (122) through the flash driver 130 according to a memory job request of the host core 110 for security requirements and host core isolation and stability, and may notify the host core 110 of the memory job result. (Task 3: HSMClient_MainFunction)

The communication unit 102 may provide an interface for network communication and manage data transmission. For example, the communication unit 102 may include modules (drivers and stacks) for communication with external devices such as a controller area network (CAN) and a local interconnect network (local interconnect network).

The input/output unit 104 is responsible for interaction with external sensors and actuators, and may include modules for processing internal and external digital and analog signals of the MCU. For example, the input/output unit 104 may include I/O drivers such as digital/analog input/output, pulse width modulation (PWM), and analog-to-digital converter (ADC).

The MCU 100 based on the AUTOSAR platform according to the embodiment of the present disclosure may perform memory jobs through a single flash driver 130 when multiple programs request memory jobs in the host core (110) or when the host core 110 and the HSM core 120 request memory jobs.

As an embodiment, multiple programs running concurrently in the host core 110 may sequentially, concurrently, or repeatedly request memory jobs through the single flash driver 130. For example, a first task and a second task of sequentially, concurrently, or repeatedly requesting memory jobs through the single flash driver 130 in the host core (110) may be executed.

The first task may be a task of performing a memory job on HostDataFlash 112 according to a request transmitted from a higher layer. For example, the first task may be a task that executes a first main function (Host data=data) for performing a first memory job until the flash driver 130 reaches an idle state according to a request transmitted from a higher layer and is terminated when the flash driver 130 is idle. The first memory job may be a memory job for data of the HostDataFlash 112 of the first core 110, and the first main function may be Fls_MainFunction supported by the AUTOSAR platform.

The second task may be a task of performing a memory job on HostCodeFlash 114 according to a request transmitted from a higher diagnostic communication layer. For example, the second task may be a task that executes a second main function (Host code=OTA) for performing a second memory job according to a request transmitted from the diagnostic communication layer, and is terminated when the flash driver 130 is idle. The second memory job may be a memory job for code of the HostCodeFlash 114 of the first core 110, and the second main function may be Ota_MainFunction supported by the AUTOSAR platform.

As an embodiment, the MCU 100 may sequentially, concurrently, or repeatedly request memory jobs through the single flash driver 130 in each of the host core 110 and the HSM core 120. For example, a first task, a second task, and a third task may be performed in the host core 110.

The first task and the second task are identical or similar to the first task and the second task described above in a case where the first task and the second task sequentially, concurrently, or repeatedly request memory jobs through the single flash driver 130 in the host core 110 are executed, and thus a detailed description thereof will be omitted.

The third task may be a task of requesting that the HSM core 120 perform a code/data memory job according to a request transmitted from a higher application layer. For example, the third task may be a task that executes a third main function (HSM Data/Code) for requesting that the HSM core 120 perform a third memory job according to a request transmitted from a higher application layer, and is terminated when a third memory job completion response is received from the HSM core 120. The third memory job may be a memory job for data or code of the HSMFLash 122 of the HSM core 120. The third main function may be HsmClient_MainFucntion supported by the AUTOSAR platform.

As described above, tasks requesting memory jobs through the flash driver in the MCU 100 based on the AUTOSAR platform according to the embodiment of the present disclosure may be designed to terminate when the flash driver 130 becomes idle.

For example, the first task and the second task may be designed to wait until the flash driver 130 becomes idle and then terminate when the flash driver 130 becomes idle without being terminated immediately even when execution of the main function MainFunction included in each task ends. Similarly, the third task may be designed to wait until the memory job completion response is received from the HSM core 120 and then terminate when the memory job completion response is received from the HSM core 120 without being terminated immediately even when execution of the main function ends.

The MCU 100 based on the AUTOSAR platform according to the embodiment of the present disclosure may perform memory jobs through the single flash driver 130 when multiple programs request memory jobs in the host core 110 or when the host core 110 and the HSM core 120 request memory jobs.

Unlike the embodiment of the present disclosure, if main functions of multiple tasks are executed without a separate synchronization device in a conventional AUTOSAR platform-based low-performance MCU, the main functions requesting memory jobs may access the flash driver without any rules, thereby causing the flash driver to be accessed repeatedly. For example, the main function of each of multiple tasks requests that the flash driver perform a memory job, and when the context is terminated while the flash driver is busy, the next main function checks whether the flash driver is idle or not, and the main function MainFunction is periodically called until the flash driver becomes idle. In other words, even if execution of the main function of a task ends, the flash driver may not be idle. In this process, due to irregular data flash memory job of the host core, code flash memory job of the host core, and data/code flash memory job of the HSM core, a duplicate write operation may occur in the flash driver in time, which may cause unexpected problems such as a write operation failure.

However, according to an embodiment of the present disclosure, multiple tasks requesting memory jobs through a flash driver in a low-performance MCU based on the AUTOSAR platform are designed to wait until the flash driver becomes idle if the flash driver is not idle even when the main functions have ended, and then terminate when the flash driver becomes idle (or terminate when a memory job completion response from the HSM core is received), and thus problems occurring when the main functions of multiple tasks are executed without a separate synchronization device in a conventional AUTOSAR platform-based low-performance MCU can be solved.

As an embodiment of the present disclosure, the first task, the second task, and the third task requesting memory jobs through the flash driver 130 in the MCU 100 based on the AUTOSAR platform may be configured to prevent preemption between tasks.

For example, by utilizing the resource function of the AUTOSAR OS, the first task, the second task, and the third task may be executed as one of tasks having the same priority, a background task, and an extended task such that preemption does not occur among the tasks.

First, the first task, the second task, and the third task performing memory jobs through the flash driver may be made to have the same priority. If the first task, the second task, and the third task have the same priority, each task has an equal execution opportunity and preemption by priority may not occur. Therefore, if the first task, the second task, and the third task have the same priority, the other task cannot preempt the other until one task ends, and thus an unnecessary race condition may not occur.

Next, all the first task, the second task, and the third task performing memory jobs through the flash driver may be executed as background tasks. A background task is a task with a low priority and can perform auxiliary functions of the system or handle periodic operations. Therefore, if all the first task, the second task, and the third task are performed as background tasks, they can be executed only during the idle time of the OS, and thus tasks do not interfere with tasks performing other main functions and a task can be prevented from preempting another task until one task is terminated.

Next, all the first task, the second task, and the third task performing memory jobs through the flash driver may be executed as extended tasks. An extended task supported by the AUTOSAR platform can operate in a non-preemptive manner to prevent preemption from other tasks having the same priority. Therefore, all the first task, the second task, and the third task may be executed as non-preemptive extended tasks such that they cannot preempt other tasks until one task is terminated.

According to the present embodiment, since multiple tasks requesting memory jobs in the low-performance multi-core MCU can be prevented from accessing the flash driver repeatedly, software issues can be minimized by preventing unexpected termination of a program running on the host core. Further, it is possible to maximize the performance of the flash driver while preventing unexpected errors during program run-time, and furthermore, enable more stable operation of OTA (Over-The-Air) solutions. Moreover, it is possible to reduce costs by preventing issues with the HSM core that cannot be debugged during mass production.

In addition, according to the present embodiment, since the problem of duplicate access to the flash driver that may occur in a low-performance multi-core MCU can be solved by utilizing the OS function of AUTOSAR, software complexity that occurs when global variables or non-standard methods are used can be reduced, and since global variables do not have to be shared between developers, collaboration between developers can be facilitated.

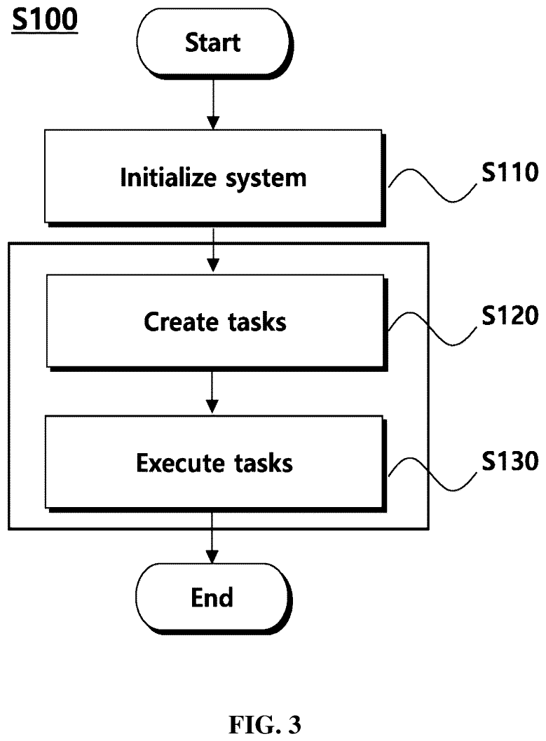

FIG. 3 to FIG. 8 are flowcharts illustrating a method of controlling a flash driver of a multi-core MCU according to an embodiment of the present disclosure.

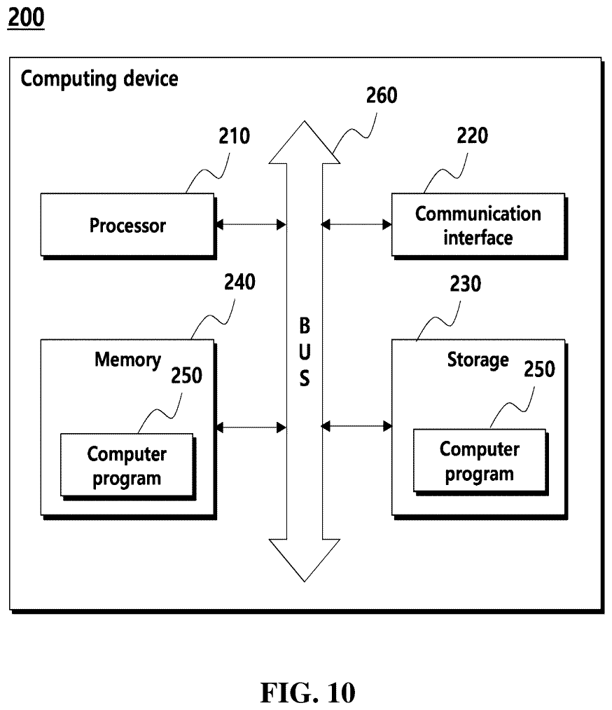

The method of controlling the flash driver of the multi-core MCU according to an embodiment of the present disclosure may be executed by a computing device 200 illustrated in FIG. 10. The computing device 200 executing the method according to the present embodiment may be a computing device equipped with an application program execution environment. The description of the subject performing some operations included in the method according to the embodiment of the present disclosure may be omitted, and in such a case, the subject may be the computing device 200.

Referring to FIG. 3, the method of controlling the flash driver of the multi-core MCU according to an embodiment of the present disclosure may include a system initialization step S110, a task creation step S120, and a task execution step S130.

The system initialization step S110 is an operation of initializing the system in order to perform the method of controlling the flash driver of the multi-core MCU, and may include HSM core booting, host core booting, OS start, and scheduler execution.

The task creation step S120 may be a step of creating multiple tasks of performing jobs through one flash driver. In step S120, each task may be created to perform an operation intended by a developer according to the properties of the task defined by the developer, such as priority, execution cycle, and stack size. The operation intended by the developer may be the method of controlling the flash driver of the multi-core MCU according to the embodiment of the present disclosure.

In the task execution step S130, the tasks created in step S120 execute main functions included in the tasks, and wait until the flash driver becomes idle if the flash driver is not idle even if execution of the main functions ends. In step S130, each task may wait until the flash driver becomes idle, and then terminate when the flash driver becomes idle.

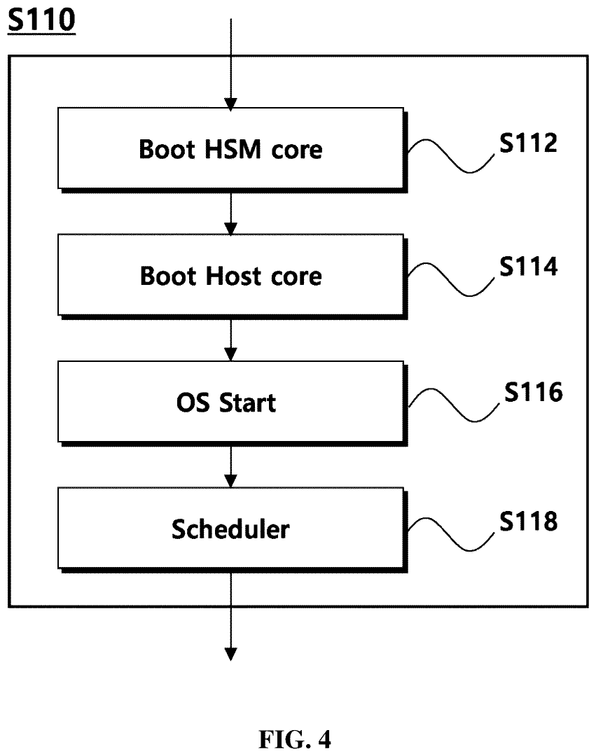

Referring to FIG. 4, the system initialization step S110 of FIG. 3 may include an HSM core booting operation S112, a host core booting operation S114, an OS start operation S116, and a scheduler execution operation S118.

The HSM core booting step S112 may be a step of initializing the HSM core and preparing a security function operation. When the HSM core is powered on in step S112, hardware components may be initialized. The initialization process may include an operation of activating the security function inside the HSM core and setting a safe state for performing tasks such as authentication and encryption.

The host core booting step S114 may be a step of initializing and booting the host core when the host core is powered on after step S112. Step S114 may include hardware device initialization, hardware self-diagnosis, bootloader execution, operating system loading, and the like.

The OS start step S116 may be a step of starting the operation of the system operating system (OS). In step S116, the booted HSM core and the operating system loaded in the host core may be initialized, and necessary system resources and drivers may be loaded.

The scheduler execution step S118 may manage multiple tasks that can be executed in the system operating system and determine the execution order. In step S118, the scheduler may efficiently allocate MCU resources and schedule jobs in consideration of priorities, execution times, and the like of tasks.

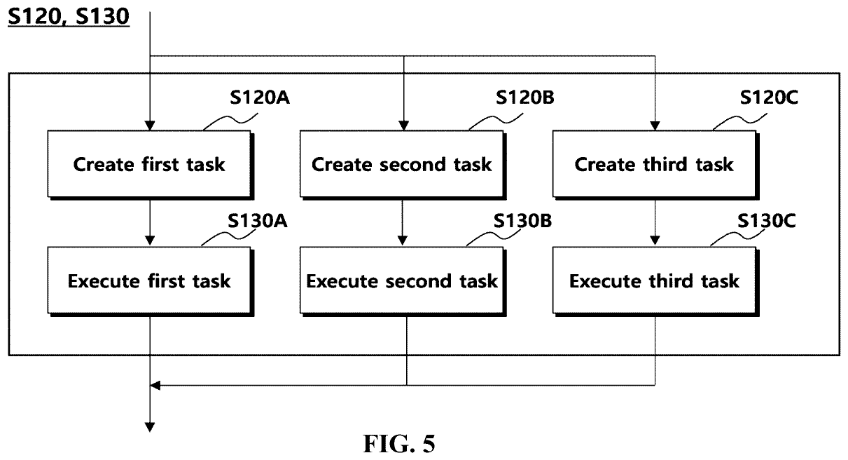

Referring to FIG. 5, multiple tasks of performing memory jobs through the flash driver may be created in the task creation step S120 of FIG. 3, and the multiple tasks created in step S120 may be executed in the task execution step S130.

As an embodiment, the task creation step S120 may include first task creation S120A, second task creation 120B, and third task creation 120C.

In step S120A, a first task of performing a first memory job on HostDataFlash 112 according to a request transmitted from a higher layer may be created. The first memory job may be a memory job with respect to data of HostDataFlash 112 of the first core 110, and a first main function may be Fls_MainFunction supported by the AUTOSAR platform.

In step S120B, a second task of performing a second memory job on HostCodeFlash 114 according to a request transmitted from a higher diagnostic communication layer may be created. The second memory job may be a memory job with respect to code of HostCodeFlash 114 of the first core 110, and a second main function may be Ota_MainFunction supported by the AUTOSAR platform.

In step S120C, a third task of requesting that the HSM core 120 perform a code/data memory job according to a request transmitted from a higher application layer may be created. A third memory job may be a memory job with respect to data or code of HSMFLash 122 of the HSM core 120, and a third main function may be HsmClient_MainFucntion supported by the AUTOSAR platform.

As an embodiment, the task execution step S130 may include first task execution S130A, second task execution 130B, and third task execution 130C.

In step S130A, the first task may execute the first main function (Host data=data) for performing the first memory job until the flash driver 130 reaches an idle state according to a request transmitted from a higher layer, and may be terminated when the flash driver 130 becomes idle.

In step S130B, the second task may execute the second main function (Host code=OTA) for performing the second memory job according to a request transmitted from the diagnostic communication layer, and may be terminated when the flash driver 130 is idle.

In step S130C, the third task may execute the third main function (HSM Data/Code) for requesting that the HSM core 120 perform the third memory job according to a request transmitted from the higher application, and may be terminated when a third memory job completion response is received from the HSM core 120.

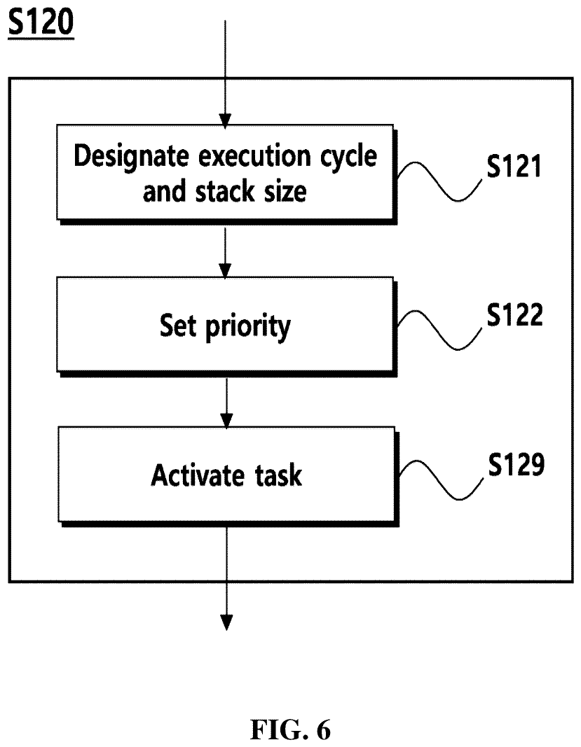

Referring to FIG. 6, the task creation step S120 of FIG. 3 according to another embodiment may include an execution cycle and stack size designation step S121, a priority setting step S122, and a task activation step S129.

In step S121, an execution cycle of each task may be set, and a memory for function calls, variable storage, and the like may be allocated while the task is being executed. The execution cycle of each task may be 10 ms, but is not limited thereto.

In step S122, a priority for each task may be set. For example, the same priority may be set for the first task, the second task, and the third task that perform memory jobs through the flash driver. If the first task, the second task, and the third task have the same priority, the other task cannot preempt the other task until one task is terminated, and thus an unnecessary race condition does not occur.

In step S129, an operation of activating each task may be performed. The activated task becomes an executable state and thus may actually be executed.

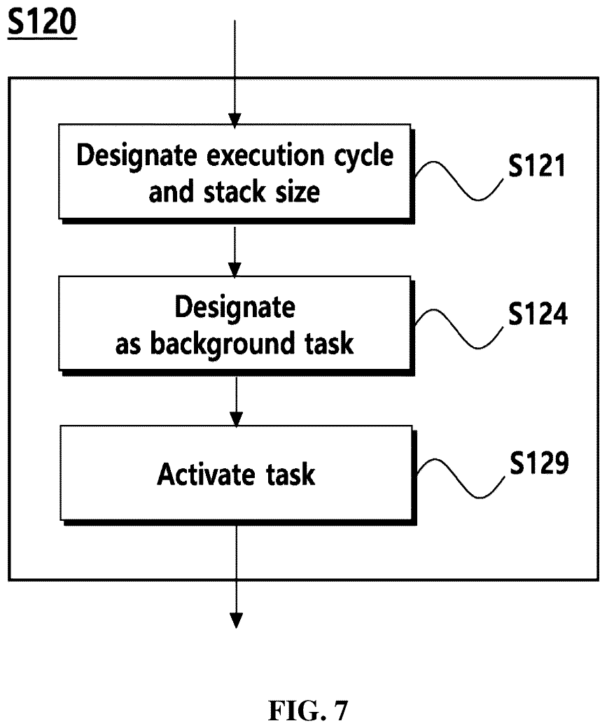

Referring to FIG. 7, the task creation step S120 of FIG. 3 according to another embodiment may include the execution cycle and stack size designation step S121, a background task designation step S124, and the task activation step S129.

In step S124, each task may be designated as a background task such that it is executed in the background. As an example, all of the first task, the second task, and the third task, which perform memory jobs through the flash driver, may be executed as background tasks. If the first task, the second task, and the third task are all executed as background tasks, they can be executed only during the idle time of the OS, and thus the tasks do not interfere with tasks performing other main functions and are prevented from preempting another task until one task is terminated.

Steps S121 and S129 are identical or similar to those described in FIG. 6, and thus detailed description thereof will be omitted.

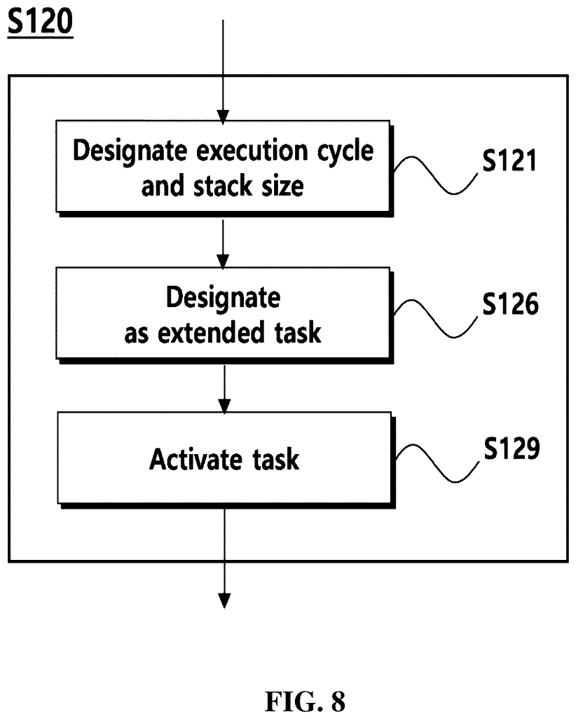

Referring to FIG. 8, the task creation step S120 of FIG. 3 according to another embodiment may include the execution cycle and stack size designation step S121, an extended task designation step S126, and the task activation step S129.

In step S126, each task may be executed as an extended task. As an example, the first task, the second task, and the third task that perform memory jobs through the flash driver may be executed as extended tasks operating in a non-preemptive manner. Since non-preemptive extended tasks supported by the AUTOSAR platform can prevent preemption from other tasks having the same priority, the first task, the second task, and the third task may be executed as non-preemptive extended tasks such that they cannot preempt other tasks until one task is terminated.

Steps S121 and S129 are the same or similar to those described in FIG. 6 and FIG. 7, and thus detailed description thereof will be omitted.

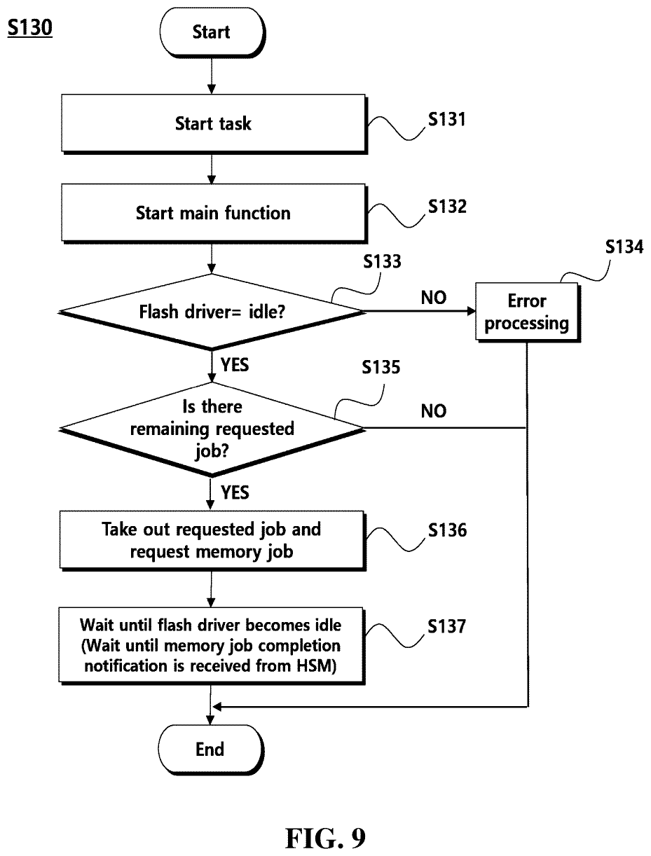

FIG. 9 is a flowchart illustrating the task execution step according to several embodiments of the present disclosure.

Referring to FIG. 9, tasks created in the task creation step may be activated to become an executable state and the tasks may be started (S131).

In step S131, the tasks may include a first task, a second task, and a third task. The first task may include a first main function for performing a first memory job on HostDataFlash 112 according to a request transmitted from a higher layer. The second task may include a second main function for performing a second memory job on HostCodeFlash 114 according to a request transmitted from a higher diagnostic communication layer. The third task may include a third main function for requesting that the HSM core perform a code/data third memory job according to a request transmitted from a higher application layer.

Next, when execution times are assigned by the scheduler, the main functions included in the tasks may be executed (S132). In step S132, the first main function of the first task may be Fls_MainFunction supported by the AUTOSAR platform, and the first memory job may be a memory job with respect to data of the HostDataFlash 112 of the first core 110. The second main function of the second task may be Ota_MainFunction supported by the AUTOSAR platform, and the second memory job may be a memory job with respect to code of the HostCodeFlash 114 of the first core 110. The third main function of the third task may be HsmClient_MainFucntion supported by the AUTOSAR platform, and the third memory job may be a memory job with respect to data or code of the HSMFLash 122 of the HSM core 120.

Next, in step S133, each task may execute the main function included therein, check whether the flash driver is idle (S133), check whether there is another requested memory job if the flash driver is idle (S135), request another memory job if there is the other requested memory job (S136), wait until the flash driver becomes idle (S137), and terminate if the flash driver is idle. Error processing S134 may be performed and the task may be terminated if the flash driver is not idle in S133 or if there are no other memory jobs in S135.

FIG. 10 is a hardware configuration diagram of an exemplary computing device that can implement the methods according to several embodiments of the present disclosure.

The computing device 200 illustrated in FIG. 10 may include one or more processors 210, a system bus 260, a communication interface 220, a memory 240 that loads a computer program 250 executed by the processor 210, and a storage 230 in which the computer program 250 is stored. Only components related to the embodiments of the present disclosure are illustrated in FIG. 10. Therefore, those skilled in the art will understand that other general components may be included in addition to the components illustrated in FIG. 10.

The computing device 200 may be implemented as an electronic device mounted on an automobile, for example.

The processor 210 may control the overall operation of each component of the computing device 200. For example, the processor 210 may be a microcontroller unit (MCU) implemented in each electronic device for a vehicle to control the operation of the electronic device.

As an embodiment, the processor 210 may be a multi-core MCU including a flash memory, a flash driver that performs a memory job on the flash memory, and a first core and a second core that use the flash driver. Here, the processor 210 may be a processor that supports a program structure based on the AUTOSAR platform. In addition, the first core may be a host core, which is a general-purpose core, and the second core may be an HSM core, which is a security-only core.

In addition, the processor 210 may be configured to include at least one of a central processing unit (CPU), a microprocessor unit (MPU), a microcontroller unit (MCU), a graphics processing unit (GPU), or any other type of processor well known in the art of the present disclosure. The processor 210 may perform operations with respect to at least one application or program for executing methods/operations according to various embodiments of the present disclosure. The computing device 200 may include one or more processors.

The memory 240 may store various types of data, commands, and/or information. The memory 240 may load one or more computer programs 250 from the storage 230 in order to execute the methods/operations according to various embodiments of the present disclosure. For example, when the computer program 250 is loaded into the memory 240, a program logic or a program module may be implemented in a state executable by the processor 210 on the memory 240. The memory 240 may be a RAM, but is not limited thereto.

The bus 260 may provide a communication function between components of the computing device 200. The bus 260 may be implemented as various types of buses, including an address bus, a data bus, and a control bus.

The communication interface 220 may be implemented including a communication module that supports wired and wireless Internet communication of the computing device 200 and various communication methods known in the technical field of the present disclosure.

The storage 230 may non-temporarily store one or more computer programs 250. The storage 230 may include a non-volatile memory such as a flash memory, a hard disk, a removable disk, or any form of computer-readable recording medium known in the art to which the present disclosure pertains.

The computer program 250 may include one or more instructions for implementing the methods/operations according to various embodiments of the present disclosure. When the computer program 250 is loaded into the memory 240, the processor 210 may execute one or more instructions to perform the methods/operations according to various embodiments of the present disclosure.

In an embodiment, the computer program 250 may be a computer program executable on the AUTOSAR (Automotive Open System Architecture) platform.

For example, the computer program 250 may include instructions for performing an operation in which a first task executes a first main function (Fls_MainFunction) for performing a first memory job of a first core and is terminated if the flash driver is idle, an operation in which a second task executes a second main function (Ota_MainFunction) for performing a second memory job of the first core and is terminated if the flash driver is idle, and an operation in which a third task executes a third main function (HsmClient_MainFunction) for requesting that the second core perform a third memory job of a second core and is terminated if a third memory job completion response is received from the second core.

According to the present embodiment, mutual preemption between multiple tasks running on a low-performance multi-core MCU can be prevented, and tasks can be prevented from being terminated until the flash driver becomes idle, thereby maximizing the performance of a single flash driver.

Various embodiments of the present disclosure and effects according to the embodiments have been described with reference to FIG. 1 to FIG. 10. Effects according to the technical idea of the present disclosure are not limited to the effects mentioned above, and other effects not mentioned will be clearly understood by those skilled in the art from the description below.

The technical idea of the present disclosure described so far may be implemented as computer-readable code on a computer-readable medium. For example, the computer-readable recording medium may be a removable recording medium (a CD, a DVD, a Blu-ray disc, a USB storage device, or a removable hard disk) or a stationary recording medium (a ROM, a RAM, or a computer fixed hard disk). A computer program recorded on a computer-readable recording medium may be transmitted to another computing device through a network such as the Internet and installed on the other computing device, and thus can be executed and used on the other computing device.

Although operations are depicted in a specific order in the figures, it should not be understood that the operations must be executed in the specific order depicted or in a sequential order or that all the depicted operations must be executed to obtain a desired result, and in certain situations, multitasking and parallel processing may be advantageous. Furthermore, in the embodiments described above, various separations of components should not be construed as necessarily requiring such separation, and program components, program modules and systems may generally be integrated into a single software product or implemented as multiple software packages.

Although the embodiments of the present disclosure have been described with reference to the attached drawings, those skilled in the art to which the present disclosure pertains will understand that the present disclosure can be implemented in other specific forms without changing the technical ideas or essential characteristics thereof. Therefore, it should be understood that the embodiments described above are exemplary and not restrictive in all respects. The protection scope of the present disclosure should be interpreted by the following claims, and all technical ideas within a scope equivalent thereto should be interpreted as being included in the scope of rights of the technical ideas defined by the present disclosure.

What is claimed is:

1. A flash driver control method performed in a microcontroller unit (MCU) including a flash memory and a flash driver configured to perform a memory job on the flash memory, the flash driver control method comprising:
executing a first task that executes a first main function for performing a first memory job, the first task being terminated when the flash driver is idle;
executing a second task that executes a second main function for performing a second memory job, the second task being terminated when the flash driver is idle; and
executing a third task that executes a third main function for requesting execution of a third memory job, the third task being terminated when a third memory job completion response is received.

2. The flash driver control method of claim 1, wherein the MCU includes a multi-core MCU including a first core and a second core.

3. The flash driver control method of claim 2, wherein each of the first core and the second core includes one or more flash memories including one or more data flash memories and one or more code flash memories.

4. The flash driver control method of claim 3, wherein each of the first, second, and third memory jobs includes a read operation, a write operation, an erase operation, or at least one combination thereof for data or code performed by the flash driver accessing the flash memory.

5. The flash driver control method of claim 1, wherein the first task, the second task, and the third task have a same priority and are executed as background tasks or extended tasks such that no preemption occurs among the first task, the second task, and the third task.

6. The flash driver control method of claim 4, wherein the first memory job and the second memory job are performed in the first core.

7. The flash driver control method of claim 6, wherein the first memory job is performed on data of a data flash memory of the first core, and the second memory job is performed on code of a code flash memory of the first core.

8. The flash driver control method of claim 4, wherein the first memory job or the second memory job is performed in the first core, and the third memory job is performed in the second core.

9. The flash driver control method of claim 8, wherein the first core includes a host core, and the second core includes an HSM core.

10. The flash driver control method of claim 8, wherein the first memory job is performed on data of a data flash memory of the first core, the second memory job is performed on code of a code flash memory of the first core, and the third memory job is performed on data of a data flash memory of the second core or is performed on code of a code flash memory of the second core.

11. A flash driver control method performed in an MCU including a flash driver configured to perform a memory job on a flash memory and a first core using the flash driver, the flash driver control method comprising:
executing a first task that executes a first main function for performing a first memory job of the first core through the flash driver, the first task being terminated when the flash driver is idle; and executing a second task that executes a second main function for performing a second memory job of the first core through the flash driver, the second task being terminated when the flash driver is idle.

12. The flash driver control method of claim 11, wherein the flash memory includes a data flash memory and a code flash memory.

13. The flash driver control method of claim 11, wherein the memory job includes a read operation, a write operation, an erase operation, or at least one combination thereof for data or code performed by the flash driver accessing the flash memory.

14. The flash driver control method of claim 11, wherein the first task and the second task have a same priority and are executed as background tasks or extended tasks such that no preemption occurs between the first and second tasks.

15. The flash driver control method of claim 11, wherein the first memory job is performed on data of a data flash memory of the first core, and the second memory job is performed on code of a code flash memory of the first core.

16. A computing device including a flash driver configured to perform a memory job on a flash memory, and a multi-core MCU including a first core and a second core using the flash driver, the computing device comprising:
one or more processors;
a communication interface configured to communicate with an external device;
a memory configured to load thereon a computer program executed by the one or more processors; and
a non-transitory storage configured to store therein the computer program,
wherein the computer program includes instructions to perform:
a first task that executes a first main function for performing a first memory job of the first core, the first task being terminated when the flash driver is idle;
a second task that executes a second main function for performing a second memory job of the first core, the second task being terminated when the flash driver is idle; and
a third task that executes a third main function for requesting that the second core perform a third memory job of the second core, the third task being terminated when a third memory job completion response is received from the second core.

17. The computing device of claim 16, wherein the first core includes a host core, and the second core includes an HSM core.

18. The computing device of claim 16, wherein the one or more processors are configured to perform the first memory job on data of a data flash memory of the first core, the second memory job on code of a code flash memory of the first core, and the third memory job on data of a data flash memory of the second core or on code of a code flash memory of the second core.

19. The computing device of claim 16, wherein the first task, the second task, and the third task have a same priority and are executed as background tasks or extended tasks such that no preemption occurs among the first task, the second task, and the third task.
